(19) United States
(12) Patent Application Publication
(10) Pub. No.: US 2026/0118451 A1
(43) Pub. Date: Apr. 30, 2026

(54) SYSTEMS AND METHODS FOR MULTI-FERROIC TUNABLE ACOUSTICALLY DRIVEN MAGNETIC RESONANCE SENSORS

(71) Applicant: Sonera, Inc., Berkeley, CA (US)

(72) Inventors: Dominic LABANOWSKI, Berkeley, CA (US); Kumar SRINIVASAN, Berkeley, CA (US); Kenny GOTLIEB, Culver CIty, CA (US); Taylor WILLIAMS, Seattle, WA (US)

(21) Appl. No.: 19/167,364

(22) PCT Filed: Mar. 20, 2024
(86) PCT No.: PCT/US2024/020805

§ 371 Date: Sep. 19, 2025

Related U.S. Application Data
(60) Provisional application No. 63/491,272, filed on Mar. 20, 2023.

(51) Int. Cl. G01R 33/18

(52) U.S. Cl. CPC G01R 33/18

(57) ABSTRACT

Acoustically driven ferromagnetic resonance (ADFMR) sensor apparatuses may be tuned by the application of a tuning voltage. A tunable ADFMR sensor apparatus may include one or more tuning electrical contacts that are configured to adjust the output of the ADFMR magnetic field sensor, e.g., by applying a voltage to adjust a magnetic property of the multiferroic magnetic material of the ADFMR magnetic field sensor. Tuning may be performed in real time, or near-real time, based on an output of the ADFMR magnetic field sensor. In some cases tuning may include field zeroing and/or adjusting the range of field measurements.

### CLAIM OF PRIORITY

This patent application claims priority to U.S. provisional Ser. No. 63/491,272, titled “SYSTEM FOR A MULTI-FERROIC TUNABLE ACOUSTICALLY DRIVEN MAGNETIC RESONANCE SENSOR,” filed on Mar. 20, 2023, and herein incorporated by reference in its entirety.

### BACKGROUND

Ferromagnetic resonance (FMR) may be used to measure magnetic properties of materials by detecting the precessional motion of the magnetization in a ferromagnetic sample. Different types of FMR include externally-driven FMR and current-driven FMR. FMR can be excited using a variety of techniques, like cavity excitation, stripline excitation, spin transfer torque, and spin orbit torque, among others. These applications are typically not compatible with device applications. They require large cavities, high power drive, and use large sample volumes in order to be effective. As such, the use of FMR has largely been restricted to large laboratory setups and to research projects. Furthermore, systems for circuit integration are not available through current implementations.

As FMR sensors have developed, there is an increasing need to improve measurement techniques and the tunability of these systems. Thus, there is a need in the field of magnetic field sensors for a tunable acoustically driven ferromagnetic resonance sensor device.

### SUMMARY OF THE DISCLOSURE

Described herein are acoustically driven ferromagnetic resonance (ADFMR) sensor. More specifically, described herein are high-sensitivity and highly tunable ADFMR sensor apparatuses (e.g., devices and systems) and methods of making and using them. The ADFMR sensors described herein may be equivalently referred to herein as ADFMR sensor apparatuses, multiferroic tunable acoustically driven magnetic resonance sensors, or multiferroic-magnetic resonance (mf-MR) magnetic field sensors.

In general, these apparatuses and methods may be configured to apply a tuning voltage to the ADFMR sensor in order to alter the properties of the ADFMR sensor. In particular, these ADFMR sensors may be configured to apply a tuning voltage to modulate the ferromagnetic resonance of a magnetostrictive material forming part of the ADFMR sensor. The application of the tuning voltage may modulate strain on the magnetostrictive material, and therefore may modulate the ferromagnetic resonance of the magnetostrictive material. This may be achieved by applying a relatively low frequency voltage (e.g., <1 MHz, including DC voltages) to either or both the magnetostrictive material and/or the piezoelectric substrate on which the magnetostrictive material is formed.

For example, described herein are tunable acoustically driven ferromagnetic resonance (ADFMR) sensor apparatuses, comprising: a piezoelectric substrate; at least one input acoustic transducer on the piezoelectric substrate and configured to activate the piezoelectric substrate to generate an acoustic wave; a magnetostrictive material on the piezoelectric substrate and configured to receive and absorb the acoustic wave based on a ferromagnetic resonance of the magnetostrictive material; at least one output acoustic transducer on the piezoelectric substrate; and a tuning electrical contact configured to apply energy to alter a property of the magnetostrictive material.

As mentioned, the tuning electrical contact may be configured to alter the property of the magnetostrictive material by modulating strain on the magnetostrictive material to alter a property of the magnetostrictive material (e.g., a magnetic property), such as the ferromagnetic resonance of the magnetostrictive material. For example, tuning electrical contact may be configured to alter the property of the magnetostrictive material by modulating strain on the magnetostrictive material to alter the ferromagnetic resonance of the magnetostrictive material.

The tuning electrical contact may be configured to create a strain gradient through the piezoelectric substrate and/or the magnetostrictive material. In some examples the tuning electrical contact is in electrical contact with the magnetostrictive material. In some examples, the tuning electrical contact is in electrical contact with the piezoelectric substrate, and in particular, with a portion of the piezoelectric substrate that underlies the magnetostrictive material. The portion of the piezoelectric substrate that underlies the magnetostrictive material may include the portion onto which the magnetostrictive material is applied, and/or the region adjacent to it or in some cases, on either side of the magnetostrictive material. In some examples, the methods an apparatuses described herein may apply a uniform strain (or approximately uniform strain) across an area including the magnetostrictive material and/or between the acoustic transducers.

In some cases the tuning electrical contact may include two or more plates that are positioned so that the magnetostrictive material is between the two or more plates. For example, the two or more plates may be the same size or may be different sized plates. The two or more plates may be positioned within the piezoelectric substrate. In some examples the two or more plates are on the top and/or bottom surface of the piezoelectric substrate. In some examples the two or more plates are on the sides of the piezoelectric substrate. The two or more plates may be positioned orthogonal to the at least one acoustic transducer and magnetostrictive material. In some examples the two or more plates are in line with the at least one input acoustic transducer and the magnetostrictive material.

In any of these examples the tuning electrical contact may comprise a plurality of tuning electrodes. In some examples the tuning electrical contact comprises a plurality of wires electrically connected to the magnetostrictive material or a region of the piezoelectric substrate underlying the magnetostrictive material. The tuning electrical contact may refer to an electrode; in some cases the magnetostrictive material may be used as the electrode via the tuning electrical contact.

In general, one or more tuning electrical contacts (e.g., electrodes) may form a pattern.

Any of these apparatuses and methods may include control logic configured to adjust the energy applied to the tuning electrical contact based on an output of the at least one output acoustic transducer. The control logic may be configured to perform any of the methods described herein. In some examples the control logic may be configured to provide feedback to adjust the tuning energy applied to the tuning electrical contact(s). The control logic may be hardware, software and/or firmware. In some cases the control logic may include circuitry configured to control the application of tuning energy to tune the apparatus. In some examples, the control logic is configured to adjust the energy applied to the tuning electrical contact in real time or near-real time.

Any of these apparatuses may include a sensing voltage source electrically connected to the at least one input acoustic transducer to apply voltage having a frequency of greater than 0.1 GHz. Any of these apparatuses may include a tuning voltage source electrically connected to the tuning electrical contact and configured to apply a voltage having a frequency of less than 100 MHz (e.g., less than 50 MHz, less than 25 MHz, less than 10 MHz, less than 5 MHz, less than 1 MHz, etc.). In some examples, the sensing voltage source is the same as the tuning voltage source, and the outputs may be modified (e.g., to have different frequencies and/or amplitudes). In some examples the sensing voltage source may be different than the tuning voltage source.

Any of these apparatuses may include one or more grounding electrodes configured to operate as a charge source/sink pair with the tuning electrical contact.

In some examples a tunable acoustically driven ferromagnetic resonance (ADFMR) sensor apparatus may include: a piezoelectric substrate; at least one input acoustic transducer on the piezoelectric substrate and configured to activate the piezoelectric substrate to generate an acoustic wave; a magnetostrictive material on the piezoelectric substrate and configured to receive and absorb the acoustic wave based on a ferromagnetic resonance of the magnetostrictive material; at least one output acoustic transducer on the piezoelectric substrate; and a tuning electrical contact configured to apply energy to alter the ferromagnetic resonance of the magnetostrictive material by modulating strain on the magnetostrictive material.

Also described herein are methods of tuning an ADFRM sensor. For example, a method for tuning an acoustically-driven ferromagnetic resonance (ADFMR) magnetic field sensor may include: activating the ADFMR magnetic field sensor by applying an activation voltage to an input acoustic transducer a piezoelectric substrate to generate an acoustic wave that is received and absorbed by a magnostrictive material on the piezoelectric substrate based on a ferromagnetic resonance of the magnostrictive material; and applying a tuning voltage to a tuning electrical contact in electrical communication with the ADFMR magnetic field sensor to tune the ADFMR magnetic field sensor while the activation voltage is applied; and sensing a magnetic field based on an output from an output acoustic transducer on the piezoelectric substrate.

Applying the tuning voltage may comprise modulating a strain on the magnostrictive material to adjust the ferromagnetic resonance of the magnetostrictive material. In some examples applying the tuning voltage comprises applying the tuning voltage to the magnetic material. For example, applying the tuning voltage may comprise applying the tuning voltage to a region of the piezoelectric substrate underlying the magnetic material. Applying the tuning voltage may comprise applying the tuning voltage between two or more plates positioned so that the magnetic material is between the two or more plates. In some examples applying the tuning voltage comprises adjust the tuning voltage based on a signal from the at least one output acoustic transducer. Applying the tuning voltage may comprise adjusting the tuning voltage in real time.

Activating the ADFMR magnetic field sensor may comprise applying an activation voltage to the at least one acoustic transducer. In some cases applying the tuning voltage comprises zeroing out an output of the ADFMR magnetic field sensor. Applying the tuning voltage may comprise modifying a sensor output of the ADFMR magnetic field sensor to a target range. Applying the tuning voltage may include applying a voltage having a frequency of less than 100 MHz (e.g., less than 50 MHz, less than 25 MHz, less than 10 MHz, less than 5 MHz, less than 1 MHz, etc.).

In some examples a method for tuning an acoustically-driven ferromagnetic resonance (ADFMR) magnetic field sensor may include: activating the ADFMR magnetic field sensor, the ADFMR magnetic field sensor comprising a piezoelectric substrate, at least one input acoustic transducer on the piezoelectric substrate that is configured to activate the piezoelectric substrate to generate an acoustic wave, a magnostrictive material configured to receive and absorb the acoustic wave based on a ferromagnetic resonance of the magnostrictive material, at least one output acoustic transducer on the piezoelectric substrate, and a tuning electrical contact; and applying a tuning voltage to the tuning electrical contact to tune the ADFMR magnetic field sensor; and sensing a magnetic field based on an output from the at least one output acoustic transducer.

All of the methods and apparatuses described herein, in any combination, are herein contemplated and can be used to achieve the benefits as described herein.

### BRIEF DESCRIPTION OF THE DRAWINGS

A better understanding of the features and advantages of the methods and apparatuses described herein will be obtained by reference to the following detailed description that sets forth illustrative embodiments, and the accompanying drawings of which:

FIG. 1 is one schematic representation of an example of a tunable multiferroic acoustically driven ferromagnetic resonance (ADFMR) sensor apparatus.

FIG. 2 is a second schematic representation of a tunable multiferroic acoustically driven ferromagnetic resonance (ADFMR) sensor apparatus.

FIG. 3 is a third schematic representation of a tunable multiferroic acoustically driven ferromagnetic resonance (ADFMR) sensor apparatus.

FIG. 4 is a fourth schematic representation of a tunable multiferroic acoustically driven ferromagnetic resonance (ADFMR) sensor apparatus.

FIG. 5 is a fifth schematic representation of a tunable multiferroic acoustically driven ferromagnetic resonance (ADFMR) sensor apparatus.

FIG. 6 is a sixth schematic representation of a tunable multiferroic acoustically driven ferromagnetic resonance (ADFMR) sensor apparatus.

FIG. 7 is a seventh schematic representation of a tunable multiferroic acoustically driven ferromagnetic resonance (ADFMR) sensor apparatus.

FIG. 8 is an eighth schematic representation of a tunable multiferroic acoustically driven ferromagnetic resonance (ADFMR) sensor apparatus.

FIG. 9 is a ninth schematic representation of a tunable multiferroic acoustically driven ferromagnetic resonance (ADFMR) sensor apparatus.

FIG. 10 is a tenth schematic representation of a tunable multiferroic acoustically driven ferromagnetic resonance (ADFMR) sensor apparatus.

FIG. 11 is an eleventh schematic representation of a tunable multiferroic acoustically driven ferromagnetic resonance (ADFMR) sensor apparatus.

FIG. 12 is a schematic of an example interdigitated transducer for a tunable multiferroic acoustically driven ferromagnetic resonance (ADFMR) sensor apparatus.

FIG. 13 is an example interferometer ADFMR circuit that may be included as part of a tunable multiferroic acoustically driven ferromagnetic resonance (ADFMR) sensor apparatus.

FIG. 14 is an example gradiometer ADFMR circuit that may be included as part of a tunable multiferroic acoustically driven ferromagnetic resonance (ADFMR) sensor apparatus.

FIG. 15 is a glossary of example circuit subcomponents.

FIG. 16 is a flowchart of an example method of tuning a tunable multiferroic acoustically driven ferromagnetic resonance (ADFMR) sensor apparatus.

FIG. 17 is a graph showing an example of the sensor output and applied voltage while applying the field-zeroing method to a tunable multiferroic acoustically driven ferromagnetic resonance (ADFMR) sensor apparatus.

FIG. 18 is an exemplary system architecture that may be used in implementing the tunable multiferroic acoustically driven ferromagnetic resonance (ADFMR) sensor apparatuses described herein.

### DETAILED DESCRIPTION

An acoustically driven ferromagnetic resonance (ADFMR) sensor apparatus may detect a magnetic field with high sensitivity based on the ferromagnetic resonance of a magnetostrictive material forming part of the ADFMR sensor. In some cases it would be beneficial to tune the ADFMR sensor. Described herein are methods and apparatuses for tuning an ADFMR sensor by applying electrical energy to one or more electrical contacts (e.g., tuning electrical contacts, including but not limited to electrodes). The tuning electrical contact may apply energy to modulate the strain on the magnetostrictive material and thereby change one or more properties of the sensor, such as changing the ferromagnetic resonance of the magnetostrictive material.

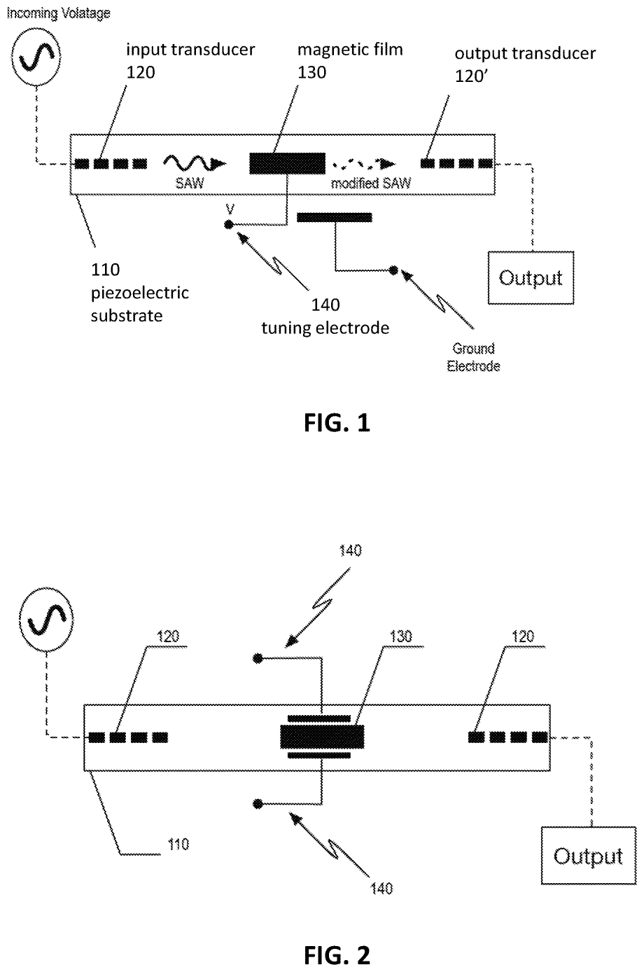

As shown in FIG. 1, a system and method for a tunable multiferroic magnetic sensor, may include a piezoelectric substrate 110, acoustic transducers 120, 120′ situated on the piezoelectric substrate, a magnetic material (e.g., a magnetostrictive film) 130 situated between the acoustic transducers, and a tuning electrode 140 situated on, or within, the piezoelectric substrate. The system and method function as a magnetic sensor that leverages the magnetic resonance properties of the system in measuring magnetic fields. Additionally, the system may leverage the multiferroic properties of the components (e.g., piezoelectric substrate 110, magnetostrictive film 130) to tune the sensor capabilities of the system (e.g., alter the sensor detection axis, zero the sensor output measurements, etc.) by applying a voltage to one or more system components. The tuning voltage applied may generally have a lower frequency than the voltage applied to the acoustic transducer(s) on the piezoelectric substrate (e.g., a frequency that is below the resonant frequency of the magnetostrictive material). For example, the tuning voltage may have a frequency that is about 1 MHz or less (e.g., between DC and 1 MHz, between DC and 0.9 MHz, between DC and 0.5 MHz, between DC and 100 kHz, between DC and 50 kHz, between DC and 1 kHz, etc.). In any of these examples, the tuning electrical contact may be configured to provide an electric field up to about 65 kV/mm, e.g., between 1 m V/mm to 100 kV/mm. For example, the tuning voltage may be between about 1 nV and 1 MV (e.g., between about 1 nV and 100 kV, between about 1 nV and 10 kV, between about 1 nV and 1 kV, between about 10 nV and 10 kV, etc.). The applied voltage may be bipolar.

Dependent on desired implementation, the systems and methods described herein may provide multiple variations for field measurements, or for enabling other devices, via this systems and methods, to make field measurements. Different implementations of the systems and methods may target various types of field measurements, focus on accuracy, provide high spatial resolution, reduce noise, and lower power consumption.

These apparatuses (e.g., systems, devices, etc.) may be used in a variety of fields in which it may be useful to detect and/or measure magnetic fields, including but limited to medical fields. For example, the systems and methods described herein may be implemented in many medical fields, such as nuclear medicine as part of human body visualization techniques (e.g. MRI, fMRI), medical monitoring tools (e.g. brain activity monitoring, heart and peripheral muscle monitoring), and the like. In this manner, these apparatuses and method may be applied to more complex functionalities, such as sleep monitoring, emotion/brain activity monitoring, brain computer interfaces, and/or other applications.

In some examples, these apparatuses and methods may be applied to the fields of augmented reality/virtual reality, wherein the system and method may enable improvements to positioning tools, such as accelerometers, determining head positioning, camera positioning, and brain activity. The chip sized system may enable itself to be incorporated into wearables, such as AR glasses, VR headsets, smart watches, headphones, chest straps (e.g. heart monitors), and fitness trackers.

In some cases, the apparatuses and methods described herein may be generally applicable to many “sensing” technologies, such as fNIR spectroscopy, lidar, impedance tomography, MRI, NMR and other magnetic sensing techniques (e.g., SERF magnetometers, NMR magnetometers, diamond NV center magnetometers).

The systems and methods described herein may provide a number of potential benefits but are not limited to always providing such benefits and are presented only as exemplary representations for how these systems and methods may be put to use. The list of benefits is not intended to be exhaustive and other benefits may additionally or alternatively exist.

One potential benefit of the systems and methods described herein is that the systems and methods may provide a field sensor device that is compact relative to comparable solutions. Where common implementations are large bench-top laboratory setups, this field sensor device may utilize magnetic resonance to measure a magnetic field without the typical space requirements. More specifically, these systems and methods may utilize ferromagnetic resonance (or other types of magnetic resonance, such as ferrimagnetic resonance). This allows these systems and methods to be implemented in many situations where it was not previously possible. These systems and methods can preferably provide a chip-scale solution that can be integrated into an integrated circuit design or a printed circuit board (PCB). The resulting sensor device may be manufactured with CMOS-compatible processing, which can make the sensor device both cheaper and more scalably produced. The system and method can use acoustically driven ferromagnetic resonance (ADFMR) devices to make a magnetic sensor that is easier to integrate.

Another potential benefit of the systems and methods described herein is that an ADFMR sensor may have enhanced sensitivity compared to other magnetic sensor technology. The system and method may be sensitive to fields over a broad frequency spectrum (0 Hz-10 GHz). This may give the advantage of enabling the system and method to be implemented in a broad range of sensor devices.

In combination with the potential benefit of a compact form factor, the system and method may provide a magnetic sensing device that has high sensitivity needed for particular applications while having significantly easier integration in terms of size and device package design. In exemplary fields of use such as magnetoencephalography systems used to measure brain activity, the system and method can achieve needed sensitivity requirements for monitoring of neuronal fields while being chip-based solution.

Another potential benefit of the systems and methods described herein may require little power to function. This system and method may be implemented using significantly less power as compared to other FMR devices. Low power requirements may give the additional benefit of less heat generation. Low heat generation enables the system and method to be implemented in temperature sensitive environments.

The ADFMR sensors described herein may generally be described as multiferroic because they have more than one primary ferroic property in the same phase; this may be because they combined a piezoelectric substrate with a magnetostrictive material. By incorporating a multiferroic approach to tunability of the system, e.g., applying tuning energy to either or both the piezoelectric substrate and/or the magnetostrictive material, the systems and methods described herein may provide the potential benefit of even further decreased power consumption to tune system components (e.g., as compared to tuning with an external field coil). In variations that minimize or reduce components to tune the system, multiferroic tunability may further provide the potential benefit of removing extraneous noise from additional current sources.

In implementations that include sensor arrays, the system and method may provide the potential benefit of an efficient manner to tune individual sensors. That is, each sensor may be individually tuned “internally” with potentially less interference from other sensors.

The system and method may be applied to nearly any field that requires field measurement. The small size, low power consumption, and high dynamic range of the system may enable incorporation of the system and method nearly anywhere. The systems and methods described herein may be particularly useful in mechanical sensor devices, magnetic imaging, replacement for SQUID devices, and in conjunction with any devices that require field measurement.

### Systems

As shown in FIG. 1, a system for a multiferroic tunable acoustically driven ferromagnetic resonance (ADFMR) sensor may include: a piezoelectric substrate 110; at least one acoustic transducer 120, 120′ situated on the piezoelectric substrate; and a magnetic film 130 situated on, or within, the piezoelectric substrate; and a tuning electrode 140 connected to the ferromagnetic film. The system functions as a magnetically “sensitive” device (i.e., a magnetic sensor or a magnetic sensor component), wherein the system leverages magnetic resonance (e.g., ferromagnetic resonance, ferrimagnetic resonance), to detect magnetic fields (or magnetic field changes) in proximity to the device. Additionally, the system may leverage the multiferroic properties of the system by using the tuning electrical contact (e.g., electrode) 140 to alter the magnetic properties, or magnetic susceptibilities of the system. Examples of altered properties and susceptibilities include: alter the effective dynamic operation range of the system, effectively remove background noise from system measurements, alter the directional susceptibility of the system, etc.

As used herein, “multiferroic” may refer to any element(s) of the system that demonstrates multiple ferroic properties, such as ferroelectricity, ferromagnetism, ferroelasticity; and/or similar properties, such as ferrimagnetism, pyroelectricity, flexoelectricity, etc. In this manner, the multiferroic element may be leveraged by an electric voltage, magnetic field, and/or mechanical constriction to alter the magnetic properties (including the magnetic response) of the system. For the sake of simplified reading, this definition also includes magnetoelastic materials. This definition also extends to composite multiferroic and magnetoelectric systems where multiple materials (e.g., a piezoelectric material and a magnetostrictive material) are coupled (e.g., via strain or exchange) to form an ‘effective’ multiferroic material.

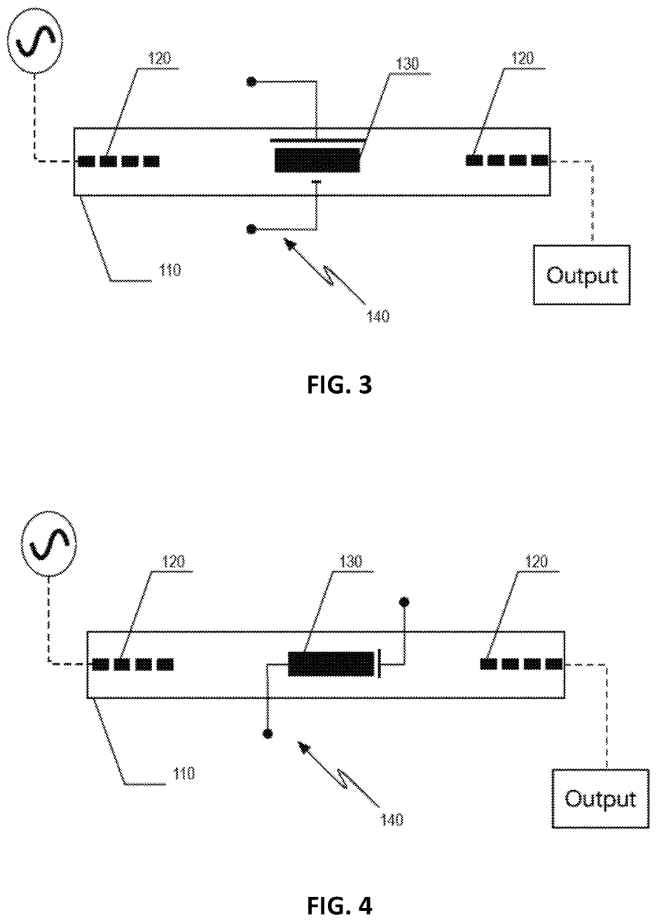

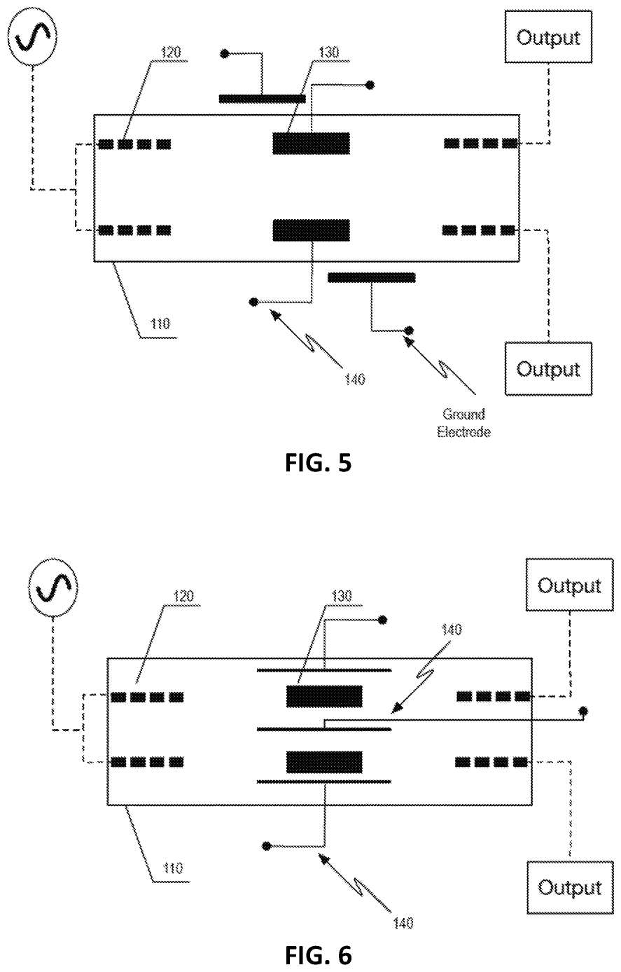

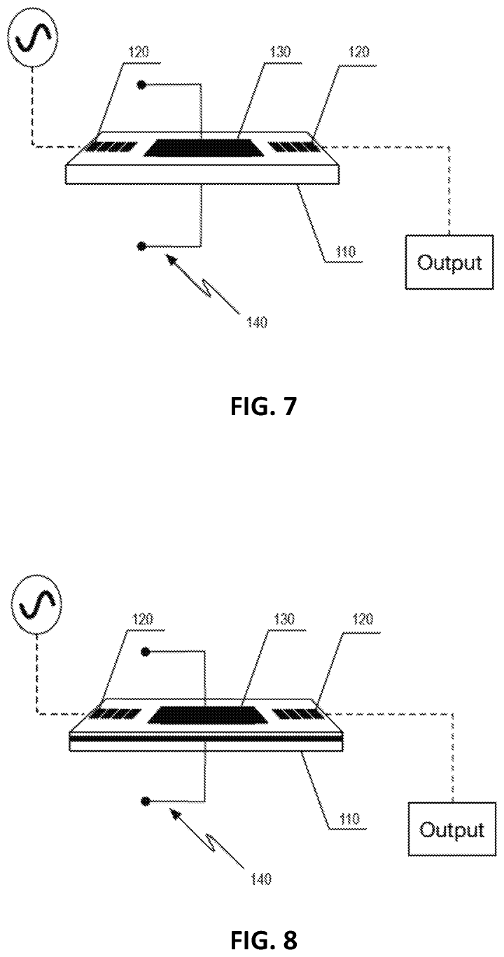

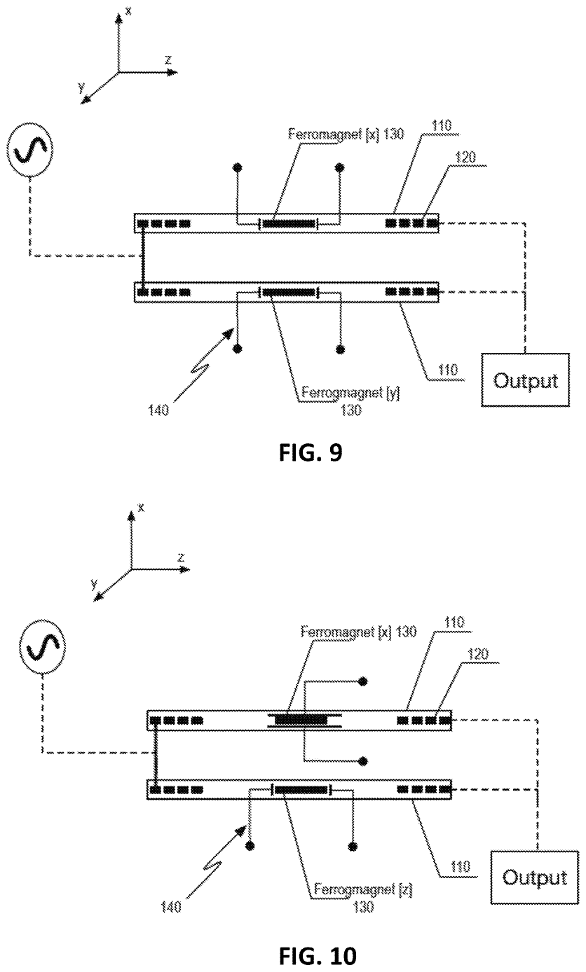

As shown in some example implementations, FIGS. 2-11, the system may have many implementations with different numbers and positionings of piezoelectric substrates 110 (e.g., FIGS. 9 and 10), acoustic transducers 120 (e.g., FIGS. 5, 6, 9, 10), ferromagnetic films 130 (e.g., FIGS. 5, 6, 9), and tuning electrical contacts (e.g., electrodes) 140. In many variations, the system as described herein, is an augmented acoustically driven ferromagnetic resonance (ADFMR) based sensor. That is, this system may comprise an augmented implementation of the ADFMR based sensor as described in the filing of U.S. patent application Ser. No. 17/120,907, filed on Dec. 14, 2020, titled “SYSTEM AND METHOD FOR AN ACOUSTICALLY DRIVEN FERROMAGNETIC RESONANCE SENSOR DEVICE”, which is hereby incorporated in its entirety. The augmented implementation of the ADFMR based sensor may comprise any compatible variation of the previously described ADFMR based sensor with additional components as described herein; wherein the additional components provide augmented test circuits and/or reference circuits that leverage their multiferroic properties to provide enhanced operation.

In many variations, the system as described herein may comprise a component in an augmented sensor array circuit, or comprise an augmented sensor array circuit. That is, the system may comprise an augmented ADFMR sensor array circuit as described in of the filing of U.S. patent application Ser. No. 17/489,978, filed on Sep. 30, 2021, titled “SYSTEM AND METHOD FOR A MAGNETIC SENSOR ARRAY CIRCUIT,” which is hereby incorporated in its entirety. In these variations, the system may comprise a plurality of augmented ADFMR sensors, wherein the additional components described herein provide augmented test circuits and/or reference circuits that leverage their properties to make field measurements.

The multiferroic tunable ADFMR sensor may include a piezoelectric substrate 110. The piezoelectric substrate enables formation and propagation of acoustic waves by the piezoelectric effect. That is, the piezoelectric substrate 110 functions as a medium to enable propagation of acoustic waves. Dependent on implementation, these may comprise surface acoustic waves (SAWs) or bulk acoustic waves (BAWs). The piezoelectric substrate 110 may comprise the main “body” of the multiferroic tunable ADFMR sensor wherein all other components are situated on, or around, the piezoelectric substrate.

The piezoelectric substrate 110 may be composed of any desired piezoelectric compound (e.g. most crystal or ceramic compounds). In many variations piezoelectric substrate 110 comprises a ferroelectric compound. In one variation a Y-cut lithium niobate substrate is used as the piezoelectric substrate 110. In another variation quartz is used as the piezoelectric substrate 110. Examples of materials that may be used for the piezoelectric substrate 110 may include: Lithium Tantalate, Lithium Niobate (e.g., YZ-cut, 128° YX, 41° YX, 64° YX, 36° YX), Quartz (e.g., ST-cut, X), Barium titanate, Langasite (e.g., Lanthanum gallium silicate), Lead zirconate titanate (PZT), lead magnesium niobate-lead titanate (PMN-PT), Aluminum Nitride, and Zinc Oxide. In some cases, thin films of piezoelectric substrate (e.g., 100 nm-to 100 um) may be formed on silicon substrates, either with or without an oxide spacer such as SiO2, ZnO, TiO2 between the Si and the piezoelectric material. In some cases, thin films may be formed on an insulating substrate such as sapphire, diamond, SiO2, etc. either with or without an oxide spacer such as SiO2, ZnO, TiO2 between the insulating substrate and the piezoelectric material.

The multiferroic tunable ADFMR sensor may include at least one acoustic transducer 120. Each acoustic transducer functions to convert an electric signal into an acoustic wave, and/or convert the acoustic wave to an RF signal (e.g. an altered electric signal). That is, each acoustic transducer 120 functions to generate and/or absorb acoustic waves (or strain waves), from an electrical signal that propagate along the piezoelectric substrate 110.

In some variations, the acoustic transducers 120 are implemented in pairs, wherein an acoustic transducer generates an acoustic wave that then propagates along the piezoelectric substrate 110 that is then absorbed by its complementary pair acoustic transducer 120. That is, a first acoustic transducer 120 converts an electric signal (e.g., an RF signal) into an acoustic wave; wherein the acoustic wave propagates in, or along, the piezoelectric substrate 110 to a second acoustic transducer; which then converts the acoustic wave to an electrical signal. Alternatively, a single acoustic transducer 110 may convert a RF test signal to an acoustic wave and then covert the acoustic wave back into a RF signal. For example, an electrical signal may be converted into an acoustic wave by an acoustic transducer 120, the acoustic wave propagates out and is then reflected back to the acoustic transducer, which then converts the acoustic wave back into an electrical signal. In other variations, the system may include multiple acoustic transducers 120 both to generate and to absorb the acoustic waves. That is, multiple acoustic transducers may be implemented, wherein a single, or multiple, RF signals may be converted to acoustic waves and/or acoustic waves converted to RF signals; once, or multiple times.

The acoustic transducer 120 preferably generates an acoustic wave appropriate to the type of system implementation. Examples of generated acoustic waves may include: surface acoustic waves (SAWs), bulk acoustic waves (BAWs), and lamb waves. The specific acoustic transducer 120 may be implementation specific. The type of acoustic transducer 120 may be dependent on the electrical signal (e.g. signal frequency, signal power), and/or the type of acoustic wave generated (e.g. surface acoustic, bulk acoustic waves). For example, in variations where the system uses Lamb waves, the acoustic transducers 120 may comprise electromagnetic acoustic transducers (EMAT). In variations where the system uses SAWs, the acoustic transducers may comprise interdigital transducers (IDTs). In variations where the system uses BAWs, the acoustic transducer 120 may comprise thin-film bulk acoustic resonators (TFBAR). Alternatively, other types of transducers (e.g. film bulk acoustic resonators, high-overtone bulk acoustic resonators) may be implemented that either generate SAWs or other types of acoustic waves.

In some variations where the system uses SAWs, the acoustic transducer 120 may comprise an IDT. The IDT may function to generate a SAW from an electrical signal (or generate an electrical signal from a SAW) using the piezoelectric effect. The IDT is a device comprising of interlocking comb-shaped arrays of metallic electrodes, forming a periodic structure, positioned on a piezoelectric substrate (e.g. quartz, lithium niobate). The IDT may have any desired configuration/shape. One example IDT configuration is shown in FIG. 12. For variations with pairs of IDTs, preferably one functions as an input IDT and one functions as an output IDT. The input IDT may convert a radio frequency (RF) electrical signal to a surface acoustic wave (SAW) using the piezo-electric effect. The output IDT functions by absorbing the SAW and converting it back to an electrical signal.

In many variations, the acoustic transducer 120 may be designed to generate acoustic waves at, or near, the resonance frequency of the magnetic film 130. This may particularly be the case for ferromagnetic, or ferrimagnetic, types of films 130. For a SAW implementation that includes a ferromagnetic type of film 130, an IDT acoustic transducer 120 may have a periodic structure with the appropriate spacing to generate SAWs at, or near, resonance of the implemented ferromagnetic film. In one example implementation with two IDT acoustic transducers 110, the length of space between the two acoustic transducers (i.e. delay line) is approximately 0.5-3 mm. In this example, a piezoelectric substrate 110 (e.g. zinc-oxide) is deposited underneath or above the two IDTs on a base (e.g. diamond base material).

The system may include a magnetic material (e.g., magnetic film) 130. In many variations, the magnetic film 130 comprises a magnetostrictive material. The magnetostrictive property may enable the magnetic film 130 to convert strain into a change in magnetization, or enable the conversion of a change in magnetization into strain. The magnetic film 130 functions to absorb acoustic waves, wherein at resonance the absorption is very sensitive to magnetic fields; thus the magnetic film may be implemented at or near resonance to be sensitive to magnetic fields. As part of the system, the magnetic film 130 may be positioned in the path of the acoustic wave (along the delay line), such that a present magnetic field shifts the magnetic material's resonant frequency with respect to the acoustic wave frequency, thereby altering the magnetic film's absorption of the acoustic wave, thus changing the propagating acoustic wave with respect to the magnitude of the magnetic field. As the thickness and length of the magnetic film 130 plays a significant role in absorption, the magnetic film may be of varying thickness and be of different length dependent on the desired implementation.

Although focus will be given to ferromagnets, the magnetostrictive material, which may be referred to herein as a magnetic (e.g., magnetostrictive) film 130 may be comprised of any type(s) of magnetostrictive material(s). Examples include: ferromagnets, ferrimagnets, antiferromagnets, paramagnets, diamagnets, etc. In some variations, the magnetic film may comprise a combination or mixture of magnetic materials (e.g. a ferromagnet and a ferrimagnetic mixture, or a combination of a ferromagnet and anti-ferromagnet or even two ferromagnets). In general, any of these magnetic films 130 may achieve resonance on a macroscopic scale (i.e. resonance beyond the excitation of individual molecules and/or atoms). Examples of ferromagnetic types of films 130 include films of: iron, nickel, and cobalt, their combinations with themselves and/or with other elements such as Ga, B, C, Cr, Ta, Ti etc., but may be any suitable type of ferromagnet. As used herein a film may refer to a relatively thin film applied onto the substrate (e.g., the piezoelectric substrate).

In some examples, the magnetostrictive material (e.g., magnetic film) 130 may comprise a composite material, wherein at least one compound within the composite material is a magnetic material. Additionally, in many variations the composite material may include other ferroic compounds, such as a ferroelectric and/or a ferroelastic material.

In SAW device type variations, the magnetic film 130 is situated in between the two acoustic resonators 120, on or within, the piezoelectric substrate 110, such that a SAW generated by the first acoustic resonator propagates through the magnetic film, to the second acoustic resonator.

In some variations, the magnetic film 130 has a spatial orientation. That is, the magnetic film 130 may be built and oriented such that EM fields with one spatial orientation (e.g. x-direction) may affect the interaction between the magnetic film and the acoustic wave, wherein fields from other (orthogonal) orientations may leave the magnetic film unaffected. In this manner, dependent on the implemented magnetic film 130, both the magnetic film (and thus the ADFMR sensor) may be sensitive to one, two, or three spatial dimensions. For example, as shown in FIG. 9, a system with an x-direction oriented ferromagnet and a y-direction ferromagnet, may be enabled to measure magnetic fields in the xy-plane.

The system may include a tuning electrode 140. The tuning electrode 140 leverages the piezoelectric properties of the piezoelectric substrate 110 and/or the magnetic film 130, to “tune” the system. That is, the tuning electrode 140 may send an electric current, create an electric field, or create a strain gradient through the piezoelectric substrate 110 and/or the magnetic film 130 to alter the magnetic properties of the magnetic material and therefore alter the sensing properties of the multiferroic tunable ADFMR sensor. The tuning electrode 140 is preferably connected to an electrical source, which may, or may not, be a part of the system; and is situated on, or around, the piezoelectric substrate 110 and/or the magnetic film 130. That is, the tuning electrode 140 is situated such that it is able to apply a voltage to the piezoelectric substrate 110 and/or the magnetic film 130 dependent on the desired implementation.

As mentioned above, the tuning electrical connection, which may be a tuning electrode 140, may “tune” the system by generating an electric field, charge gradient (and therefore strain gradient), or current through the piezoelectric substrate 110 and/or the magnetic film 130. In this manner, the tuning electrical contact 140, through charge and/or current generation, may leverage the ferroic properties (e.g., flexoelectricity, piezoelectricity, inverse flexoelectricity, converse flexoelectricity, converse piezoelectric effect, etc.) to alter the magnetic sensing properties of the system.

In some variations, the tuning electrode 140 may tune the system to provide improved spatial resolution of measurement of an external magnetic field. In one example, the tuning electrical contact (e.g., tuning electrode) 140 may provide fine grain compensation in response to measurement of the external magnetic field. In another example, the tuning electrode 140 may pattern external magnetic properties. This may be used for matched filtering, or other types of filtering and noise rejection. In a third example, the tuning electrical contact 140 may be used to change the magnetic anisotropy axis i.e., the sensitive direction of the magnetic film 130, thereby improving spatial resolution.

In some variations, the tuning electrical contact 140 may tune the magnetic film 130 and/or the piezoelectric substrate 110 to tune the operating dynamic range. That is, the tuning electrical contact 140 may modify components in response to an external magnetic field such that the system response to the magnetic field is improved (e.g., the system operates in a regime where response to the magnetic field is maximized). The dynamic range tuning may be incorporated to shift the response curve of the system to an external signal (e.g., to improve or dampen the signal response) to any range, dependent on the desired implementation.

In some variations, the tuning electrical contact 140 may tune the magnetic film 130 and/or the piezoelectric substrate 110 to adjust the magnetic anisotropy axis of magnetic film. That is, in response to a magnetic field, the tuning electrode 140 may dynamically change the sensitive axis of the sensor. In some implementations, wherein the sensor is moving (or a magnetic field is constantly shifting), the tuning electrical contact 140 may constantly adjust the sensitive axis of the system in accordance to the orientation of the system with respect to the field.

Additionally, in some variations, tuning the sensitive orientation of the system with respect to a magnetic field may be implemented such that the sensor may be able to make multi-axis measurements. For example, the tuning electrical contact 140 of a single ADFMR sensor may fluctuate between two voltages to enable the sensor to measure a field along multiple planar orientations. In one implementation, the tuning electrode 140 may initially orient the ADFMR sensor to measure a B-field along the x-direction. After some time, the tuning electrode 140 may alter the voltage applied to of the ADFMR sensor, such that the ADFMR sensor is then measuring the B-field along the y-direction. These two measurements may then be combined to give an xy planar measurement of the B-field. Alternatively, the tuning electrode 140 may gradually tune the ADFMR sensor, such that some angle of sensitivity of the B-field is scanned and measured by the ADFMR sensor.

In another variation of the tuning of the ADFMR sensor orientation. The tuning electrode 140 may alter the orientation of sensors to minimize cross-talk by nearby sensors. In another variation of the tuning of the ADFMR sensor orientation the tuning electrode 140 may alter the sensor orientation to improve the signal-to-noise ratio (SNR). This may be incorporated as an algorithm. Additionally or alternatively, this may occur dynamically.

In another variation of the tuning of the ADFMR sensor orientation, the tuning electrode 140 may rotate the sensitive axis of the ADFMR sensor in time (or turn off/on) to upconvert low frequency fields out of the 1/f region. That is, the tuning electrode 140 may “turn on/off” the magnetic sensitivity of the sensor along a given orientation at a set rate (f); enabling a shift of a frequency field by the set rate. This would enable shifting signals from undesirable frequency regimes (e.g., move the frequency field outside of high noise regimes). In some variations, the tuning electrode 140 may tune different layers of the ADFMR heterostructure.

In variations, wherein the system comprises multiple ADFMR sensors (e.g., an array of sensors on a chip), each ADFMR sensor may have an independent tuning electrode 140 that could control each sensor bias configuration independently. For example, adjacent magnetic films 120 (e.g., from adjacent ADFMR devices or as part of a single gradiometer device) may be set to have equal and opposite slopes/offsets. In another example, each tuning electrode 140 could be used to align adjacent ADFMR devices. Alternatively, each tuning electrode 140 may be used tune the ADFMR devices to measure orthogonal signals.

Generally, the tuning electrodes 140 may be used to tune each ADFMR device to measure a time-domain (or spatial-domain) superposition that is of interest. For example, the tuning electrode 140 may be used for frequency domain multiplexing by modulating a first ADFMR sensor at position ‘a’ along direction x1, and a second ADFMR sensor at position ‘b’ along direction x2 at different frequencies and combining their outputs. Since the combined output signal includes two different frequency domains, one from each ADFMR device, information from either ADFMR sensor may be extracted independently from a single output signal. This allows for the reuse of expensive, large, and power-consuming signal processing and digitization electronics following the ADFMR device output.

The positioning and method of positioning of the tuning electrode 140 may be dependent on implementation. The tuning electrode 140 may be positioned at any angle in any 2D or 3D patterning on, or around, the other system components. In some variations, as shown in FIG. 1, the tuning electrode 140 may directly connect to the magnetic film 130, thereby enabling the magnetic film to also function as part of the tuning electrode.

In other variations (e.g., as shown in FIGS. 2, 3, 5, 6, 9, 10, 11) the tuning electrode 140 may be positioned as plates on top, below, and/or within the piezoelectric substrate 110, wherein opposing plates may, or may not, be identical in size. Dependent on implementation, these plates may be situated at any angle with regards to the piezoelectric substrate 110 and/or magnetic film 130.

In other variations, the tuning electrode 140 may comprise a single plate and an opposing wire connected to the magnetic film 130 (e.g., as shown in FIGS. 4 and 8). Asymmetric wire and plate positioning may enable generation of gradients within the magnetic film 130 and/or the piezoelectric substrate 110.

In some variations, with multiple magnetic films 130 (e.g., as shown in FIGS. 5, 6, 9 and 10) the tuning electrodes 140 may include varying and/or complementary configurations. For example, as shown in FIG. 5, one magnetic film 130 may be used as a source and another magnetic film as a sink. In another example, as shown in FIG. 6, the tuning electrode 140 may be situated as multiple plates on the piezoelectric substrate 110 separated by the magnetic film 130. In this example, the “outer” tuning electrodes 140 may send or receive a voltage from the central tuning electrode.

In some variations, as shown in FIGS. 9 and 10, the positioning of the tuning electrodes may be dependent on the orientation of the magnetic film 130. For example, tuning electrodes may be positioned orthogonal to the orientation of measurement (e.g., FIG. 9), or inline with the orientation of magnetic film (e.g., FIG. 10).

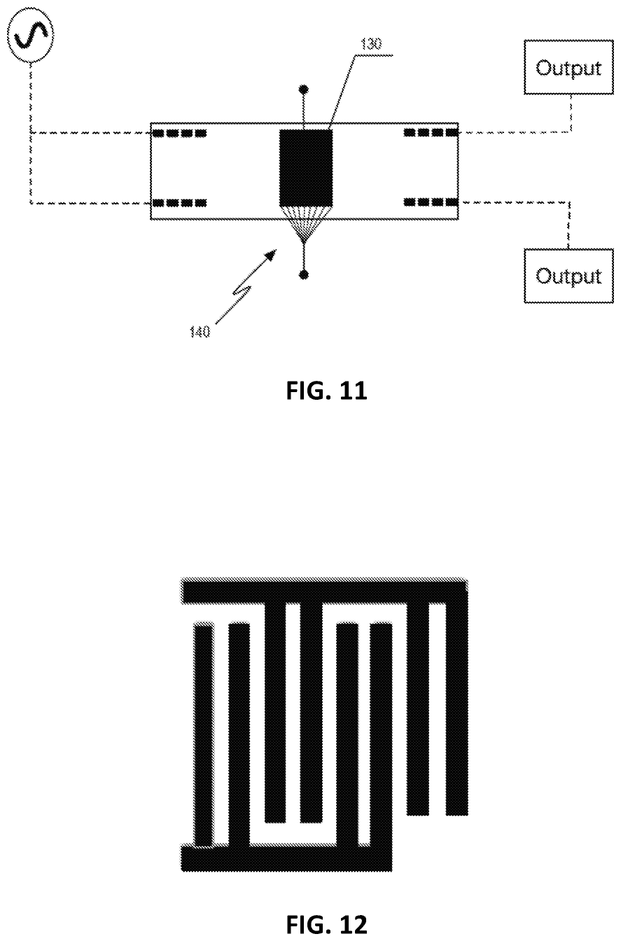

In some variations, as shown in FIG. 11, the tuning electrical contact 140 may comprise sets of wires connecting to the magnetic film 130 (or alternatively to the piezoelectric substrate 110). The positioning of the multiple wires may be symmetric, or asymmetric, around the magnetic film 110. Dependent on how each wire is activated, constant voltage may be applied across the magnetic film or a gradient may be generated across the magnetic film. In general, it may be advantageous to apply the tuning energy (e.g., tuning voltage) in a pattern such as a gradient, and alternating pattern, etc. In the example shown in FIG. 11, each wire or line of the tuning electrical contact may be separately or jointly addressable.

In any of these variations, the tuning electrical contact 140 may be configured to tune the system in “real time”. That is, the system, once placed in a magnetic field, may activate the tuning electrical contact (e.g., tuning electrode) 140 to adjust the dynamic range almost instantaneously (e.g., on the order of 100 nanoseconds to seconds).

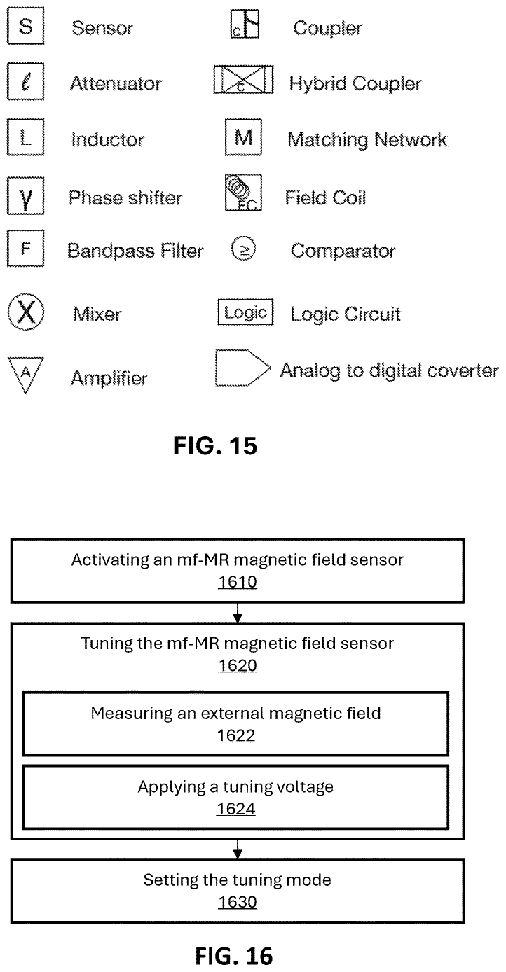

In many variations, the system may have additional components. These components can include control components (e.g., processor), components that improve functionality (e.g., attenuators, couplers, inductors, phase shifters, amplifiers, matching networks), power sources, grounding electrodes, etc. A sample list of components and their circuit symbols are shown in FIG. 15, wherein the ADFMR sensor, as described above, is referred to as the sensor(S).

In any of these variations, the system may include a power source. The power source functions as an energy source, providing an electrical signal to the system. In some variations, the power source is an electronic oscillator. The electronic oscillator functions to provide the system with an oscillating voltage, i.e. an alternating current (AC) power signal, wherein the power from the oscillator is used to activate the sensor circuit. Alternatively, other types of currents may be used, e.g. direct current (DC).

In some variations, the electronic oscillator is a voltage-controlled oscillator (VCO). Preferably the frequency of the oscillator is in the order of gigahertz. More preferably ˜2 GHz. High frequency pulsing of the oscillator may enable fast turn-on and turn-off times of the sensor. Fast turn-on/turn-off times may be on the order of microseconds or faster. As the ADFMR sensor may function with MHz oscillations, the oscillator may alternatively be in any range that enables ADFMR functionality, that is in the order of MHz to GHz. Dependent on implementation, tuning electrode 140 may use be connected to a system power (e.g., as described here above), or may have a distinct power source (e.g., a battery).

In any of these variations, the system may include one, or more, grounding electrodes. The grounding electrode may be positioned on the system in complement to the tuning electrode 140, such that the tuning electrode and the grounding electrode may function as a charge source/sink pair. In many examples, the grounding electrode may be positioned above, or underneath, the magnetic film 130, enabling current flowing to the magnetic film from the tuning electrode 130. In implementations, with multiple tuning electrodes 130 (e.g., as shown in FIG. 5). multiple grounding electrodes may be implemented (e.g., directly beneath each magnetic film 130). Alternatively, a single grounding electrode may be implemented above, or beneath, the piezoelectric substrate 110. In some implementations, this single grounding electrode may span the x-y dimension of all magnetic films 130 on the piezoelectric substrate 110 (e.g., as a planar conducting sheet situated underneath the piezoelectric substrate).

Any of these systems may include a signal detector. The signal detector may measure the output power signal from the ADFMR sensor. Since the output power signal may have been perturbed by an external field, the output power signal may be used to determine the field strength. The signal detector may additionally include noise reduction functionalities. In one variation, the signal detector may perform a Fourier transform to separate the desired output signal from other extraneous Electromagnetic (EM) waves. For example, an input acoustic transducer may additionally generate extraneous EM waves. The signal detector may perform a Fast Fourier Transform to isolate and remove these extraneous waves from the desired signal. Due to the time delay of acoustic wave propagation, as compared to EM wave propagation, other time dependent methods may be used to separate acoustic waves from EM waves. For example, in one implementation, the electronic oscillator may be cycled on and off for fixed periods of time, enabling measurement of the propagating acoustic waves during the electronic oscillator off cycle, thus potentially removing undesired signals.

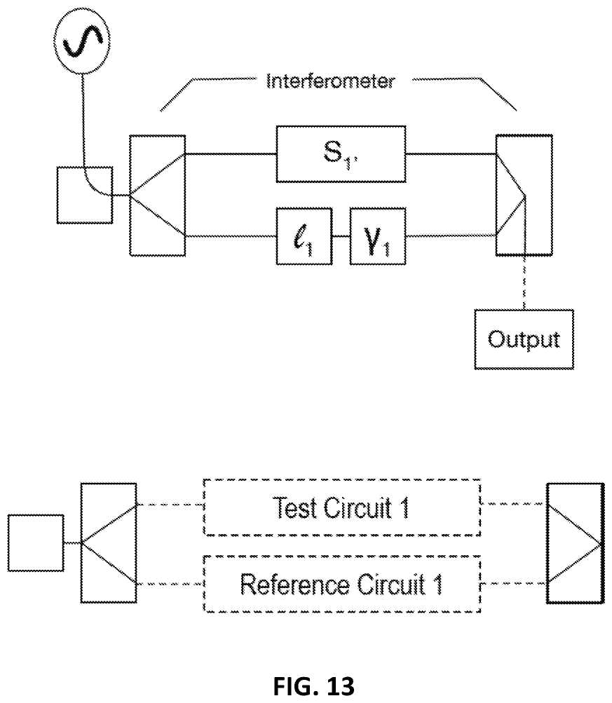

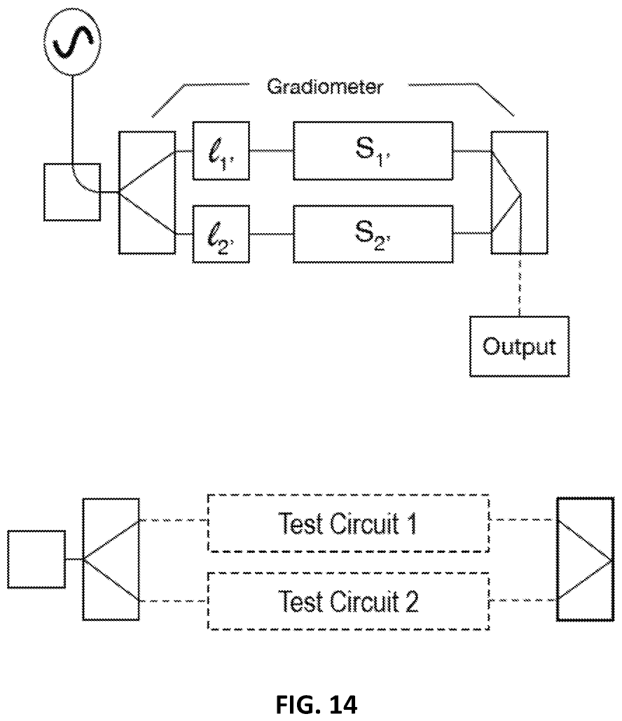

In some variations, as shown in the example FIG. 12, the multiferroic tunable ADFMR sensor may be a SAW device as part of an acoustically driven ferromagnetic (ADFMR) sensor. That is, in one SAW device example, the system may comprise: two IDT acoustic resonators 120, an input IDT and an output IDT; positioned along a piezoelectric substrate 110; wherein a ferromagnetic (or ferrimagnetic) magnetic film 130 is positioned along the piezoelectric substrate in between the two IDTs; and a tuning electrode 140 connected to the magnetic film. The specific configuration and shape of the SAW device may vary dependent on implementation. That is the multiferroic tunable ADFMR sensor in a SAW implementation (S) may be incorporated as part of a sensor device/circuit. Example variations include: having a single SAW device per ADFMR circuit; having spatially oriented ferromagnets (one or more) on the SAW device; for a multidimensional field sensor, utilizing a single SAW device with a single ferromagnet (or ferrimagnet) between multiple ADFMR circuits; utilizing a single SAW device with multiple ferromagnets, either as an interferometer implementation (e.g., as shown in FIG. 13) or gradiometer implementation (e.g., FIG. 14), having multiple distinctly oriented ferromagnets in series (e.g. as part of a serial multi-dimensional sensor). Specific variations may include fewer, or additional components, as desired or necessary.

In circuit implementations, the tuning electrodes 140 may be incorporated differently for each multiferroic tunable ADFMR sensor. As mentioned above, they be positioned along the axis of sensitivity, orthogonal, or using any other positioning within the system.

### EXAMPLES

FIG. 16 schematically illustrates one method for tuning a multiferroic-magnetic resonance (mf-MR) magnetic field sensor. This mf-MR sensor may include first activating the mf-MR magnetic field sensor 1610, e.g., by applying a voltage (e.g., an AC voltage) to the sensor. The mf-MR magnetic field sensor may then be tuned 1620, and may be set into a tuning mode 1630. Tuning the mf-MR magnetic field sensor may include measuring an external field 1622 and applying a tuning voltage 1624; these steps may be iteratively performed. The tuning voltage may be incrementally applied to the multiferroic element of the magnetic field sensor to adjust effective field measurement of the mf-MR magnetic field sensor. The method may leverage the multiferroic properties of the magnetic field sensor to alter the effective range of magnetic field measurements. This may provide many different functionalities dependent on the desired use case. For example, the method may function as a bandpass filter (removing undesirable signal regimes). Additionally or alternatively, the method may also comprise a “field-zeroing” technique; thereby shifting the range of field measurements to a linear regime for the magnetic field sensor.

The method may be incorporated with any multiferroic sensing device, wherein an electric charge applied across a multiferroic material may be leveraged to tune the system properties. The method may be particularly useful for tuning the system as described above, but may be generally implemented with any applicable system.

In one use case of the method may enable the magnetic field sensor to measure an external magnetic field in a desired magnetic field range that optimizes the capabilities of the field sensor, while simultaneously reducing undesirable noise that may affect the measurement. In many variations, it is desired to have this field range to be in the neighborhood of zero, but this is not always the case. As used herein, the term “field-zeroing” (field-zeroing mode, field-zero, etc.) may be generally used to refer to moving the effective measured magnetic field range to any desired range around any desired value. That is, field-zeroing may equally refer to moving the measured field range to around zero, as to around any other desired value.

In some cases, as shown in FIG. 16, activating the mf-MR magnetic field sensor 1610 may enable magnetic field measurements using the magnetic field sensor. Activating the mf-MR magnetic field sensor 1610, may comprise running an electric signal through the sensor device, as mentioned for the system described above, but may include any other activation method.

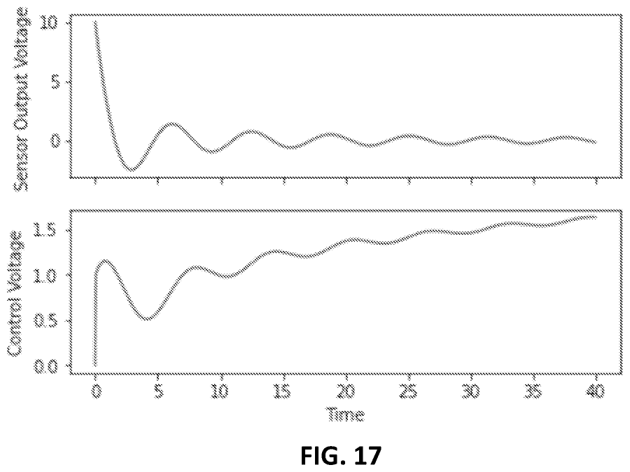

The method may further include tuning the mf-MR magnetic field sensor functions to adjust the magnetic field sensor output to a desired sensor output bandwidth, (e.g., zeroing the sensor output) 1620. As shown in FIG. 17, by increasing (or decreasing) a tuning voltage, the ferroic properties of the mf-MR sensor may be leveraged to change the sensor properties, thereby modifying the sensor output to the desired output range. In FIG. 17 the sensor output voltage (e.g., in m V or V) may be used to adjust the control voltage (also in m V or V). Thus, tuning the mf-MR magnetic field sensor 1620 may include: at the mf-MR magnetic field sensor, measuring an external magnetic field 1622; and at the mf-MR magnetic field sensor, applying a tuning voltage 1624, in response to the magnetic field measurement. In this manner, tuning the mf-MR magnetic field sensor 1620 may comprise a loop that adjusts the sensor output by incrementally applying a tuning voltage 1624 in response to the current sensor output (block 1622).

Measuring the external magnetic field, which may include measuring an external magnetic field, may function to implement the activated mf-MR sensor in proximity of a magnetic field, such that the sensor measures the magnetic field. As there is generally a background field, measuring an external magnetic field 1622 may be initially incorporated in a region with “no” magnetic field to measure the background field (e.g., background field on Earth, due to magnetization). In this manner, block 1620 may be used to zero the background field prior to other external field measurements (e.g., as part of a calibration method).

Applying the tuning voltage, which may include applying a tuning voltage 1624, functions to effectively change the sensor output (i.e., increasing or decreasing the sensor output) by applying a voltage (i.e., increasing or decreasing an applied voltage) to the multiferroic element of the mf-MR magnetic field sensor. In some cases applying a tuning voltage 1624 may occur through the use of a tuning electrode connected to the multiferroic element of the mf-MR sensor. Applying a tuning voltage 1624, may change the voltage input to the multiferroic element of the sensor in response to the measured field from block 1622. In this manner, block 1624 may increase, or decrease, the applied voltage to the multiferroic element of the sensor thereby, increasing, or decreasing, the output of the sensor.

Setting the tuning mode may set the mode of operation. The modes of operation may vary significantly dependent on the implementation, particularly due to the incorporated system. Setting the tuning mode 1630 may set how the method steps are implemented and how often they are implemented). Setting the tuning mode 1630 may be a user implemented step (e.g., a user chosen mode of operations, in real time or as part of a setup configuration), an automated step (e.g., a system control/procedure may be used to choose the operating mode), a fixed operating mode (e.g., the implemented system may allow only a single operating mode), and/or a combination of user implemented and automated modes of operation. Examples of tuning modes that may be included are: field-zeroing modes, and bandpass filter modes.

Setting the tuning mode 1630 may include a field-zeroing mode. The field-zeroing mode may function to set the baseline measurement of an external magnetic field to zero (or alternatively set the baseline measurement of an external magnetic field to some other fixed value). In the field-zeroing mode, block 1620 may be repeated until the external magnetic field strength is measured at, or around, zero. That is, an external magnetic field is measured 1622, and in response to that measured magnetic field; a tuning voltage is applied to multiferroic element of the mf-MR magnetic field sensor to bring the output of the sensor closer to zero 624. In a field-zeroing mode, tuning the mf-MR sensor 20 may thus be repeatedly performed until the output of the sensor is at, or approximately, zero. The field-zeroing mode, by itself, may be incorporated as a calibration method (e.g., for example to remove background noise prior to “actual” field measurements). Additionally or alternatively, the field-zeroing mode may be used for measurement of fairly “constant” magnetic fields. By applying a field-zeroing mode, the magnitude of the magnetic field may be shifted to a linear regime of the mf-MR magnetic field sensor, thereby enabling more precise measurements of the external field.

Setting a tuning mode 1630, may also include an instantaneous operating mode. In an instantaneous operating mode, the method may be implemented a single time, or a set number of times, to completion. The instantaneous mode may call for the method operation to occur immediately, and/or when a certain condition has been met. For example, a calibration instantaneous mode may be activated one minute after the system has been turned on, or an instantaneous mode field-zeroing operation may be implemented if a magnetic field measurement changes by an order of a magnitude.

Setting a tuning mode 1620 may also include a continuous mode of operation. In the continuous mode, the method may be called at regular intervals. These regular intervals may be time intervals, i.e., a frequency/rate (e.g., the in a continuous mode, the method may be activated every 1 ms). Additionally or alternatively, the continuous mode may be called at regular intervals not-necessarily based on time. For example, an mf-MR magnetic field sensor may be part of a moving device (e.g., a wristwatch, vehicle, etc.). In this example, in a continuous mode may activate the method whenever a certain movement requirement has been met. This may be distance traveled (e.g., input received by GPS), change in orientation (e.g., input received about the angle of device detected by a gyroscope, etc.).

The continuous mode of operation may enable a plethora of functionalities to the method. For example, the continuous mode set at a certain frequency bandwidth may enable the method to be implemented as a bandpass filter. In one implementation, the continuous mode set at a frequency bandwidth with field-zeroing may enable removal of magnetic fields lower than the frequency bandwidth, thereby enabling functionality as a high bandpass filter. In another example, as part of a moving magnetic sensor device, the continuous mode, in conjunction with field-zeroing, may enable constant recalibration of the magnetic field sensor enabling measurement of external magnetic fields of all ranges while constantly removing background field noise.

The apparatuses and methods described herein may also be used to tune the apparatus to compensate for thermal effects, e.g., the effect of temperature change on the sensor apparatus. For example, any of these apparatuses may be configured to electrically tune the strain in the piezoelectric substate to compensate for the effect of temperature change. Tuning the piezoelectric to accommodate for temperature changes may be done in combination with tuning of the magnetic material or may be done separately. These apparatuses and methods may include a temperature sensor; in some cases the energy applied to the tuning electrical contact may be adjusted (e.g., modulated) by a temperature sensor and/or a temperature sensitive modulator.

Any of the methods and apparatuses described herein may include the use of “pilot tone,” e.g., a calibration signal that may be applied to the sensing voltage and/or the tuning voltage. For example, these methods and apparatuses may include components to enable use of pilot tones such as, but not limited to, one or more pilot tone generator modules, which may function to apply pilot tones. The pilot tones may be tones at known frequencies in amplitude and phase, and may be sine waves, square waves, triangle waves, or any other modulation shape. These may be used as ground truth and rotate I and Q channels to create enhanced (“ideal”) R channel and to separate signal output due to phase vs. amplitude changes in the RF signal. These may also be used to separate noise in the output signal due to phase vs. amplitude changes in the RF signal. This may be helpful in ADFMR sensors as most of the close-in carrier noise is due to phase noise, while the amplitude of ADFMR elements is dependent on magnetic field. Thus, through proper separation of amplitude and phase components, carrier noise can primarily be shunted to one output channel (i.e., Q), while signal is primarily shunted to the other (i.e., I). The pilot tone generator modules may be trimmers or other suitable components.

In another example, a pilot tone can be applied to the tuning voltage. By monitoring the output of this pilot tone, it can be determined whether the tuning voltage should be increased, decreased, or held constant in order to maintain sensor operation at a desired transmission peak (i.e., optimal transmission through the device) or a desired absorption peak (i.e., optimal carrier rejection via the subtraction loop).

In the case that a single trimmer cannot produce a suitably orthogonal modulation (in the phase/attenuation space), a modulation of two non-orthogonal trimmers can form a set of basis vectors that together can generate orthogonal modulation. Alternatively, when the rotation operation is performed in IQ space, the modulation can be rotated to the angle corresponding to the modulation's linear combination of phase and amplitude modulation, thus correcting this non-orthogonality. A pilot tone generator module may include or be integrated with existing components such as a DAC that controls the analog voltage / phase trimmers which may be integrated into the system. The system can include an integrated MCU that may set the details of the pilot tones. The pilot tone parameters may alternatively be set by a dedicated oscillator. Instead of control via trimmers, frequency modulation to control phase may also be used to generate a pilot tone. In some pilot tone variations, tones are applied at different frequency for amplitude and phase. For example, a pilot tone variation can work by applying a tone at different frequency for amplitude and phase. In some variations, such tones could be Gold codes, Walsh codes, or other suitable types of codes. A mixer used in the system may have random phase between the LO and the RF ports, such that the mixer I and Q outputs will both have some combination of tones at both the amplitude and phase frequencies. As the amplitude frequency peak should primarily show up on I, and the phase frequency peak should primarily show up on Q, a linear combination of the I and Q outputs may be applied (either in analog or digital) to end up with I′ and Q′, where I′ has only amplitude information, and Q′ has only phase information.

### System Architecture

The systems and methods of the embodiments can be embodied and/or implemented at least in part in connection with a computing system including at least one machine configured to receive a computer-readable medium storing computer-readable instructions. The multiferroic ADFMR acoustically driven magnetic resonance sensor enabled system and method above can be integrated within a computing system such that programmatic control of such a device may be used, wherein the computing system can make use of a sensor input providing EM field sensor data. The computing system can include one or more ADFMR sensor enabled systems. The instructions can be executed by computer-executable components integrated with the application, applet, host, server, network, website, communication service, communication interface, hardware/firmware/software elements of a user computer or mobile device, wristband, smartphone, or any suitable combination thereof. Other systems and methods of the embodiment can be embodied and/or implemented at least in part as a machine configured to receive a computer-readable medium storing computer-readable instructions. The instructions can be executed by computer-executable components integrated with apparatuses and networks of the type described above. The computer-readable medium can be stored on any suitable computer readable media such as RAMs, ROMs, flash memory, EEPROMs, optical devices (CD or DVD), hard drives, floppy drives, or any suitable device. The computer-executable component can be a processor, but any suitable dedicated hardware device can (alternatively or additionally) execute the instructions.

In one variation, a system comprising of one or more computer-readable mediums storing instructions that, when executed by the one or more computer processors, cause a computing platform to perform operations comprising those of the system or method described herein such as: measuring a magnetic field; setting a loop bandwidth; and tuning a multiferroic magnetic resonance (mf-MR) sensor.

In one variation, a non-transitory computer-readable medium storing instructions that, when executed by one or more computer processors of a computing platform, can cause the computing platform to perform operations of the system or method described herein such as: measuring a magnetic field; setting a loop bandwidth; and tuning a multiferroic magnetic resonance (mf-MR) sensor.

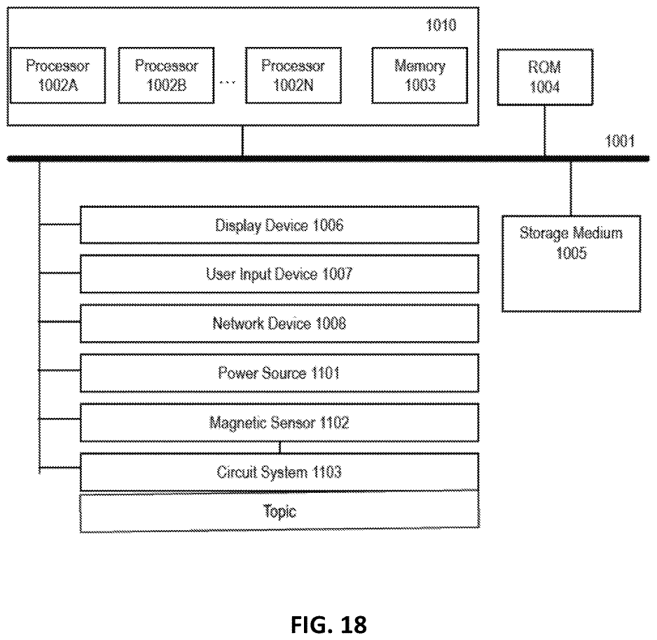

FIG. 18 is an exemplary computer architecture diagram of one implementation of the system. In some implementations, the system is implemented in a plurality of devices in communication over a communication channel and/or network. In some implementations, the elements of the system are implemented in separate computing devices. In some implementations, two or more of the system elements are implemented in same devices. The system and portions of the system may be integrated into a computing device or system that can serve as or within the system.

The communication channel 1001 interfaces with the processors 1002A-1002N, the memory (e.g., a random access memory (RAM)) 1003, a read only memory (ROM) 1004, a processor-readable storage medium 1005, a display device 1006, a user input device 1007, and a network device 1008. As shown, the computer infrastructure may be used in connecting a power source 1101, and ADFMR circuit 1102, a detector circuit 1103, and/or other suitable computing devices. Alternatively, the system described above may be enabled as a self-contained system that is connected to the computer infrastructure.

The processors 1002A-1002N may take many forms, such CPUs (Central Processing Units), GPUs (Graphical Processing Units), microprocessors, ML/DL (Machine Learning/Deep Learning) processing units such as a Tensor Processing Unit, FPGA (Field Programmable Gate Arrays, custom processors, and/or any suitable type of processor.

The processors 1002A-1002N and the main memory 1003 (or some sub-combination) can form a processing unit 1010. In some embodiments, the processing unit includes one or more processors communicatively coupled to one or more of a RAM, ROM, and machine-readable storage medium; the one or more processors of the processing unit receive instructions stored by the one or more of a RAM, ROM, and machine-readable storage medium via a bus; and the one or more processors execute the received instructions. In some embodiments, the processing unit is an ASIC (Application-Specific Integrated Circuit). In some embodiments, the processing unit is a SoC (System-on-Chip). In some embodiments, the processing unit includes one or more of the elements of the system.

A network device 1008 may provide one or more wired or wireless interfaces for exchanging data and commands between the system and/or other devices, such as devices of external systems. Such wired and wireless interfaces include, for example, a universal serial bus (USB) interface, Bluetooth interface, Wi-Fi interface, Ethernet interface, near field communication (NFC) interface, and the like.

Computer and/or Machine-readable executable instructions comprising of configuration for software programs (such as an operating system, application programs, and device drivers) can be stored in the memory 1003 from the processor-readable storage medium 1005, the ROM 1004 or any other data storage system.

When executed by one or more computer processors, the respective machine-executable instructions may be accessed by at least one of processors 1002A-1002N (of a processing unit 1010) via the communication channel 1001, and then executed by at least one of processors 1001A-1001N. Data, databases, data records or other stored forms data created or used by the software programs can also be stored in the memory 1003, and such data is accessed by at least one of processors 1002A-1002N during execution of the machine-executable instructions of the software programs.

The processor-readable storage medium 1005 is one of (or a combination of two or more of) a hard drive, a flash drive, a DVD, a CD, an optical disk, a floppy disk, a flash storage, a solid state drive, a ROM, an EEPROM, an electronic circuit, a semiconductor memory device, and the like. The processor-readable storage medium 1005 can include an operating system, software programs, device drivers, and/or other suitable sub-systems or software.

All publications and patent applications mentioned in this specification are herein incorporated by reference in their entirety to the same extent as if each individual publication or patent application was specifically and individually indicated to be incorporated by reference. Furthermore, it should be appreciated that all combinations of the foregoing concepts and additional concepts discussed in greater detail below (provided such concepts are not mutually inconsistent) are contemplated as being part of the inventive subject matter disclosed herein and may be used to achieve the benefits described herein.

Any of the methods (including user interfaces) described herein may be implemented as software, hardware or firmware, and may be described as a non-transitory computer-readable storage medium storing a set of instructions capable of being executed by a processor (e.g., computer, tablet, smartphone, etc.), that when executed by the processor causes the processor to control perform any of the steps, including but not limited to: displaying, communicating with the user, analyzing, modifying parameters (including timing, frequency, intensity, etc.), determining, alerting, or the like. For example, any of the methods described herein may be performed, at least in part, by an apparatus including one or more processors having a memory storing a non-transitory computer-readable storage medium storing a set of instructions for the processes(s) of the method.

While various embodiments have been described and/or illustrated herein in the context of fully functional computing systems, one or more of these example embodiments may be distributed as a program product in a variety of forms, regardless of the particular type of computer-readable media used to actually carry out the distribution. The embodiments disclosed herein may also be implemented using software modules that perform certain tasks. These software modules may include script, batch, or other executable files that may be stored on a computer-readable storage medium or in a computing system. In some embodiments, these software modules may configure a computing system to perform one or more of the example embodiments disclosed herein.

As described herein, the computing devices and systems described and/or illustrated herein broadly represent any type or form of computing device or system capable of executing computer-readable instructions, such as those contained within the modules described herein. In their most basic configuration, these computing device(s) may each comprise at least one memory device and at least one physical processor.

The term “memory” or “memory device,” as used herein, generally represents any type or form of volatile or non-volatile storage device or medium capable of storing data and/or computer-readable instructions. In one example, a memory device may store, load, and/or maintain one or more of the modules described herein. Examples of memory devices comprise, without limitation, Random Access Memory (RAM), Read Only Memory (ROM), flash memory, Hard Disk Drives (HDDs), Solid-State Drives (SSDs), optical disk drives, caches, variations or combinations of one or more of the same, or any other suitable storage memory.

In addition, the term “processor” or “physical processor,” as used herein, generally refers to any type or form of hardware-implemented processing unit capable of interpreting and/or executing computer-readable instructions. In one example, a physical processor may access and/or modify one or more modules stored in the above-described memory device. Examples of physical processors comprise, without limitation, microprocessors, microcontrollers, Central Processing Units (CPUs), Field-Programmable Gate Arrays (FPGAs) that implement softcore processors, Application-Specific Integrated Circuits (ASICs), portions of one or more of the same, variations or combinations of one or more of the same, or any other suitable physical processor.

Although illustrated as separate elements, the method steps described and/or illustrated herein may represent portions of a single application. In addition, in some embodiments one or more of these steps may represent or correspond to one or more software applications or programs that, when executed by a computing device, may cause the computing device to perform one or more tasks, such as the method step.

In addition, one or more of the devices described herein may transform data, physical devices, and/or representations of physical devices from one form to another. Additionally or alternatively, one or more of the modules recited herein may transform a processor, volatile memory, non-volatile memory, and/or any other portion of a physical computing device from one form of computing device to another form of computing device by executing on the computing device, storing data on the computing device, and/or otherwise interacting with the computing device.

The term “computer-readable medium,” as used herein, generally refers to any form of device, carrier, or medium capable of storing or carrying computer-readable instructions. Examples of computer-readable media comprise, without limitation, transmission-type media, such as carrier waves, and non-transitory-type media, such as magnetic-storage media (e.g., hard disk drives, tape drives, and floppy disks), optical-storage media (e.g., Compact Disks (CDs), Digital Video Disks (DVDs), and BLU-RAY disks), electronic-storage media (e.g., solid-state drives and flash media), and other distribution systems.

A person of ordinary skill in the art will recognize that any process or method disclosed herein can be modified in many ways. The process parameters and sequence of the steps described and/or illustrated herein are given by way of example only and can be varied as desired. For example, while the steps illustrated and/or described herein may be shown or discussed in a particular order, these steps do not necessarily need to be performed in the order illustrated or discussed.

The various exemplary methods described and/or illustrated herein may also omit one or more of the steps described or illustrated herein or comprise additional steps in addition to those disclosed. Further, a step of any method as disclosed herein can be combined with any one or more steps of any other method as disclosed herein.

The processor as described herein can be configured to perform one or more steps of any method disclosed herein. Alternatively or in combination, the processor can be configured to combine one or more steps of one or more methods as disclosed herein.

When a feature or element is herein referred to as being “on” another feature or element, it can be directly on the other feature or element or intervening features and/or elements may also be present. In contrast, when a feature or element is referred to as being “directly on” another feature or element, there are no intervening features or elements present. It will also be understood that, when a feature or element is referred to as being “connected”, “attached” or “coupled” to another feature or element, it can be directly connected, attached or coupled to the other feature or element or intervening features or elements may be present. In contrast, when a feature or element is referred to as being “directly connected”, “directly attached” or “directly coupled” to another feature or element, there are no intervening features or elements present. Although described or shown with respect to one embodiment, the features and elements so described or shown can apply to other embodiments. It will also be appreciated by those of skill in the art that references to a structure or feature that is disposed “adjacent”another feature may have portions that overlap or underlie the adjacent feature.

Terminology used herein is for the purpose of describing particular embodiments only and is not intended to be limiting of the invention. For example, as used herein, the singular forms “a”, “an” and “the” are intended to include the plural forms as well, unless the context clearly indicates otherwise. It will be further understood that the terms “comprises” and/or “comprising,” when used in this specification, specify the presence of stated features, steps, operations, elements, and/or components, but do not preclude the presence or addition of one or more other features, steps, operations, elements, components, and/or groups thereof. As used herein, the term “and/or” includes any and all combinations of one or more of the associated listed items and may be abbreviated as “/”.

Spatially relative terms, such as “under”, “below”, “lower”, “over”, “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if a device in the figures is inverted, elements described as “under”, or “beneath” other elements or features would then be oriented “over” the other elements or features. Thus, the exemplary term “under” can encompass both an orientation of over and under. The device may be otherwise oriented (rotated 90 degrees or at other orientations) and the spatially relative descriptors used herein interpreted accordingly. Similarly, the terms “upwardly”, “downwardly”, “vertical”, “horizontal” and the like are used herein for the purpose of explanation only unless specifically indicated otherwise.

Although the terms “first” and “second” may be used herein to describe various features/elements (including steps), these features/elements should not be limited by these terms, unless the context indicates otherwise. These terms may be used to distinguish one feature/element from another feature/element. Thus, a first feature/element discussed below could be termed a second feature/element, and similarly, a second feature/element discussed below could be termed a first feature/element without departing from the teachings of the present invention.

In general, any of the apparatuses and methods described herein should be understood to be inclusive, but all or a sub-set of the components and/or steps may alternatively be exclusive and may be expressed as “consisting of” or alternatively “consisting essentially of”the various components, steps, sub-components or sub-steps.

As used herein in the specification and claims, including as used in the examples and unless otherwise expressly specified, all numbers may be read as if prefaced by the word “about” or “approximately,” even if the term does not expressly appear. The phrase “about” or “approximately” may be used when describing magnitude and/or position to indicate that the value and/or position described is within a reasonable expected range of values and/or positions. For example, a numeric value may have a value that is +/−0.1% of the stated value (or range of values), +/−1% of the stated value (or range of values), +/−2% of the stated value (or range of values), +/−5% of the stated value (or range of values), +/−10% of the stated value (or range of values), etc. Any numerical values given herein should also be understood to include about or approximately that value, unless the context indicates otherwise. For example, if the value “10” is disclosed, then “about 10” is also disclosed. Any numerical range recited herein is intended to include all sub-ranges subsumed therein. It is also understood that when a value is disclosed that “less than or equal to” the value, “greater than or equal to the value” and possible ranges between values are also disclosed, as appropriately understood by the skilled artisan. For example, if the value “X” is disclosed the “less than or equal to X” as well as “greater than or equal to X” (e.g., where X is a numerical value) is also disclosed. It is also understood that the throughout the application, data is provided in a number of different formats, and that this data represents endpoints and starting points, and ranges for any combination of the data points. For example, if a particular data point “10” and a particular data point “15” are disclosed, it is understood that greater than, greater than or equal to, less than, less than or equal to, and equal to 10 and 15 are considered disclosed as well as between 10 and 15. It is also understood that each unit between two particular units are also disclosed. For example, if 10 and 15 are disclosed, then 11, 12, 13, and 14 are also disclosed.

Although various illustrative embodiments are described above, any of a number of changes may be made to various embodiments without departing from the scope of the invention as described by the claims. Optional features of various device and system embodiments may be included in some embodiments and not in others. Therefore, the foregoing description is provided primarily for exemplary purposes and should not be interpreted to limit the scope of the invention as it is set forth in the claims.

The examples and illustrations included herein show, by way of illustration and not of limitation, specific embodiments in which the subject matter may be practiced. As mentioned, other embodiments may be utilized and derived there from, such that structural and logical substitutions and changes may be made without departing from the scope of this disclosure. Such embodiments of the inventive subject matter may be referred to herein individually or collectively by the term “invention” merely for convenience and without intending to voluntarily limit the scope of this application to any single invention or inventive concept, if more than one is, in fact, disclosed. Thus, although specific embodiments have been illustrated and described herein, any arrangement calculated to achieve the same purpose may be substituted for the specific embodiments shown. This disclosure is intended to cover any and all adaptations or variations of various embodiments. Combinations of the above embodiments, and other embodiments not specifically described herein, will be apparent to those of skill in the art upon reviewing the above description.

1. A tunable acoustically driven ferromagnetic resonance (ADFMR) sensor apparatus, the apparatus comprising:
a piezoelectric substrate;
at least one input acoustic transducer on the piezoelectric substrate and configured to activate the piezoelectric substrate to generate an acoustic wave;
a magnetostrictive material on the piezoelectric substrate and configured to receive and absorb the acoustic wave based on a ferromagnetic resonance of the magnetostrictive material;
at least one output acoustic transducer on the piezoelectric substrate; and
a tuning electrical contact configured to apply energy to alter a property of the magnetostrictive material.

2. The apparatus of claim 1, wherein the tuning electrical contact is configured to alter the property of the magnetostrictive material by modulating strain on the magnetostrictive material to alter a magnetic property of the magnetostrictive material.

3. The apparatus of claim 1, wherein the tuning electrical contact is configured to alter the property of the magnetostrictive material by modulating strain on the magnetostrictive material to alter the ferromagnetic resonance of the magnetostrictive material.

4. The apparatus of claim 1, wherein the tuning electrical contact is configured to create a strain gradient through the piezoelectric substrate and/or the magnetostrictive material.

5. The apparatus of claim 1, wherein the tuning electrical contact is in electrical contact with the magnetostrictive material.

6. The apparatus of claim 1, wherein the tuning electrical contact is in electrical contact with a portion of the piezoelectric substrate that underlies the magnetostrictive material.

7. The apparatus of claim 1, wherein the tuning electrical contact comprises two or more plates that are positioned so that the magnetostrictive material is between the two or more plates.

8. The apparatus of claim 7, wherein the two or more plates comprise different sized plates.

9. The apparatus of claim 7, wherein the two or more plates are positioned within the piezoelectric substrate.

10. The apparatus of claim 1, wherein the two or more plates are positioned orthogonal to the at least one acoustic transducer and magnetostrictive material.

11. The apparatus of claim 1, wherein the two or more plates are in line with the at least one input acoustic transducer and the magnetostrictive material.

12. The apparatus of claim 1, wherein the tuning electrical contact comprises a plurality of tuning electrodes.

13. The apparatus of claim 1, wherein the tuning electrical contact comprises a plurality of wires electrically connected to the magnetostrictive material or a region of the piezoelectric substrate underlying the magnetostrictive material.

14. The apparatus of claim 1, further comprising control logic configured to adjust the energy applied to the tuning electrical contact based on an output of the at least one output acoustic transducer.

15. The apparatus of claim 14, wherein the control logic is configured to adjust the energy applied to the tuning electrical contact in real time.

16. The apparatus of claim 1, further comprising a voltage source electrically connected to the at least one input acoustic transducer to apply voltage having a frequency of greater than 0.1 GHz.

17. The apparatus of claim 1, further comprising a tuning voltage source electrically connected to the tuning electrical contact and configured to apply a voltage having a frequency of less than 100 MHz.

18. The apparatus of claim 1, further comprising one or more grounding electrodes configured to operate as a charge source/sink pair with the tuning electrical contact.

19. A tunable acoustically driven ferromagnetic resonance (ADFMR) sensor apparatus, the apparatus comprising:
a piezoelectric substrate;
at least one input acoustic transducer on the piezoelectric substrate and configured to activate the piezoelectric substrate to generate an acoustic wave;
a magnetostrictive material on the piezoelectric substrate and configured to receive and absorb the acoustic wave based on a ferromagnetic resonance of the magnetostrictive material;
at least one output acoustic transducer on the piezoelectric substrate; and
a tuning electrical contact configured to apply energy to alter the ferromagnetic resonance of the magnetostrictive material by modulating strain on the magnetostrictive material.

20. A method for tuning an acoustically-driven ferromagnetic resonance (ADFMR) magnetic field sensor, the method comprising:
activating the ADFMR magnetic field sensor by applying an activation voltage to an input acoustic transducer on a piezoelectric substrate to generate an acoustic wave that is received and absorbed by a magnostrictive material on the piezoelectric substrate based on a ferromagnetic resonance of the magnostrictive material; and
applying a tuning voltage to a tuning electrical contact in electrical communication with the ADFMR magnetic field sensor to tune the ADFMR magnetic field sensor while the activation voltage is applied; and
sensing a magnetic field based on an output from an output acoustic transducer on the piezoelectric substrate.

21-31. (canceled)
